(19) United States
(12) Patent Application Publication
(10) Pub. No.: US 2012/0119280 A1
(43) Pub. Date: May 17, 2012

(54) Charge Trap Non-Volatile Memory

(76) Inventor: Paolo Tessariol, Montebelluna (TV) (IT)

(21) Appl. No.: 12/944,125

(22) Filed: Nov. 11, 2010

(51) Int. Cl. H01L 29/792; H01L 21/336

(52) U.S. Cl. 257/315; 438/288; 257/E21.423; 257/E29.309

(57) ABSTRACT

A charge trapping non-volatile memory may be made with a charge trapping medium including a pair of dielectric layers sandwiching a metal or semimetal layer. The metal or semimetal layer may exhibit a lower energy level than either of the adjacent sandwiching charge trapping layers, creating a good electron sink and, in some embodiments, resulting in a thinner charge trapping medium.

### BACKGROUND

This relates generally to charge trap non-volatile memories, sometimes called charge trap flash (CTF).

Charge trapping non-volatile memories generally trap charge, not in a floating gate, but in a potential well in a dielectric material, such as silicon nitride or in a wide band gap semiconductor material. They are advantageous in suppressing unwanted cell to cell interference and leakage current. If the charge trap has states at lower energy than band edges of overlying blocking dielectric and an underlying injection tunnel layer, charge may be effectively stored in a charge trapping layer.

However, the charge trapping and charge retention capabilities of the charge trapping layer is a function of its thickness, resulting in a poor efficiency device in some cases.

### BRIEF DESCRIPTION OF THE DRAWINGS

FIG. 1 is a greatly enlarged, cross-section view of one embodiment of the present invention;

FIG. 2 is an energy band diagram for the stack of FIG. 1 in the flat band condition; and

FIG. 3 is an energy band diagram for the structure shown in FIG. 1 in the programmed condition.

### DETAILED DESCRIPTION

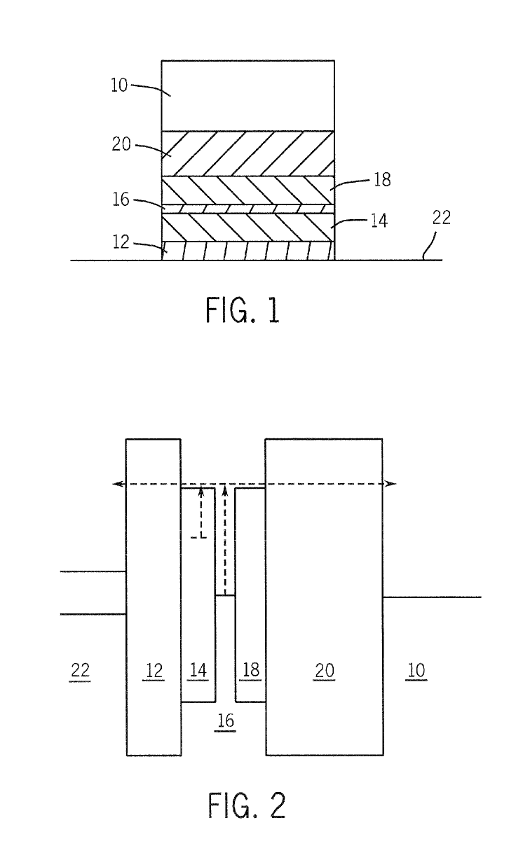

Referring to FIG. 1, a charge trapping non-volatile memory, such as an NAND flash memory, includes a metal or semimetal layer 16 interposed within a charge trap medium composed of dielectric layers 14 and 18 that sandwich the layer 16.

In some embodiments, the metal or semimetal layer 16 may have a lower energy level than the surrounding layers 14 and 18, making the composite charge trapping medium composed of the layers 14, 16, and 18 more effective in trapping and retaining charge. In fact, the layer 16 acts as a charge sink for charge carriers already trapped in the dielectric layers 14 and 18.

The layer 16 may be made of titanium, tantalum, or other metals, metal alloys, or semimetals. The thickness of the layer 16 may be less than fifteen nanometers and on the order of one to ten nanometers in some embodiments. In some embodiments the metal deposition process may induce some agglomeration into metal layer inducing the formation of a non-continuous metallic islands layer. In some embodiments the metal deposition process may induce the complete melting of metallic layer resulting in a final doping of dielectric stack with consequent modification of charge traps density and energy.

In some embodiments, the energy of charge trapped in the metal or semimetal layer 16 is within the forbidden gap of the dielectric layers 14 and 18.

The dielectric layers 14 and 18 may be made of silicon nitride or other dielectric materials having a relative (i.e. relative to a void) dielectric constant greater than 3.9. The lower dielectric layer 14 may have a thickness from zero to ten nanometers and the upper trapping layer 18 may have a thickness from one to ten nanometers in some embodiments. The upper layer 18 may be silicon nitride, for example, formed by atomic layer deposition or chemical vapor deposition on the metal or semimetal layer 16. Thus, in some embodiments, the charge trapping medium may be about 30 nanometers or less in thickness.

In some embodiments, the metal or semimetal layer 16 is thinner than the combined dielectric layers 14 and 18. In some embodiments, the metal or semimetal layer 16 is thinner than either dielectric layer 14 or 18.

An injection tunnel layer 12 may be a single layer or a composite engineered barrier in some embodiments. For example, the layer 12 may be a single silicon dioxide layer or band engineered multilayer stack. Advantageously, the injection tunnel layer may be quite thin, less than 15 nanometers, in some embodiments, for example, about 5 nanometers.

The blocking layer 20 may be a high dielectric constant material having a relative dielectric constant greater than 3.9. The layer 20 may be silicon dioxide in some embodiments. It may be tunable in material and thickness to the particular cell architecture.

The gate electrode 10 may be any conventional gate electrode material, including polysilicon or metal. The substrate 22 may include a source and drain (not shown).

In some embodiments, a self-aligned etch may be used to form the stack, including the gate electrode 10 down to the injection tunnel layer 12. As a result, the stack may have self-aligned edges as shown in FIG. 1.

In some embodiments, a lower energy state is provided, through the use of the metal or semimetal layer 16, for charge trapping into the dielectric layers 14 and 18, stabilizing the system into a charged state. During writing, a higher energy barrier for charge escape across the blocking layer 20 inhibits early saturation phenomenon in some embodiments. The higher energy barrier may provide a larger working window and may limit the charge flow through the stack to improve endurance in some embodiments.

In some embodiments, the advantages of a pure charge stack in the form of a thin injection tunnel layer 12, lower thickness across the entire stack and no fringing effect in a dense matrix may be combined with advantages of an interstitial metallic charge gatherer, namely, a higher energy barrier for better charge retention and less current through the stack during writing.

In some embodiments, when a complete cell to cell insulation of the charge trap medium is possible, any three dimensional architecture for high density storage may be used, including cells with gate wrap around or in other cells where a limited thickness charge trap stack is desired.

Referring to FIG. 2, the energy band diagram shows that the layer 16 has a lower energy layer than either of the charge trapping layers 14 or 18. Thus, the energy barriers for electrons sunk into the metal or semimetal layer 16 is higher than in devices where electrons are trapped in a bounded state, resulting in better charge retention in some embodiments.

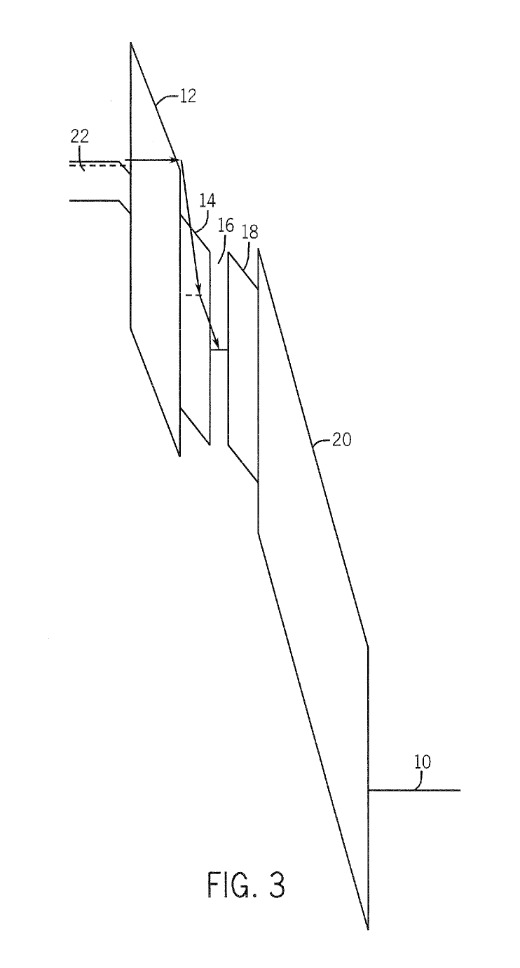

In FIG. 3, the programmed energy band diagram is illustrated with arrows indicating the concept of electrons cascading through the dielectric layer 14 into the metal or semimetal layer 16 acting as an electron sink.

Charge retention capability may be further improved, in some embodiments, due to the charge quantum confinement into the metal sink provided by the metal or semimetal layer 16 pursuant to the Coulomb blockade effect. For the 20 nanometer architecture, the ratio between elementary charge and capacitance of the structure is in the range of 30 to 40 mV, resulting in a Coulomb blockade effect of up to 350 to 450 K.

In some embodiments, charge retention is improved. Also, backward charge currents during writing may be reduced in some embodiments. These backward currents induce early saturation, limiting the working window of the memory cell. Reducing the backward current improves cell reliability.

Programming may be achieved by positively charging a control gate 10 and applying an appropriate bias to source and drain regions (not shown). Hot electrons from the substrate 22 are trapped in trap sites inside the charge trapping medium in order to program the memory cell. Erasing may be implemented by negatively charging the control gate while biasing the source and drain regions. Holes from the substrate are trapped in the charge trapping medium. The trapped holes recombine with available electrons to erase the cell.

Commonly, a programming operation may be followed by a program verify operation at an appropriate threshold voltage level. Then it is determined whether the programming was sufficient by reading the cell using a control gate voltage lower than the program voltage. Cells that are not programmed to the appropriate level are reprogrammed, for example, using an incremental step pulse programming scheme until they pass the programming test.

When a positive voltage is applied to the control gate, a field is induced under the control gate in the substrate channel. If that voltage is high enough to exceed the threshold voltage for the device, electrons from the source transfer to the drain region while also tunneling toward the control gate. However, the electrons become trapped in the charge trapping medium. The accumulated charge in the charge trapping medium stores a value of one. This value is retained until erased by the refreshing process using a voltage of the opposite polarity. If the desired voltage to be stored is a zero, then a negative voltage is applied to the control gate. This enables holes from the channel that tunnel through towards the control gate to be retained within the charge trapping medium.

The cells are read by applying a voltage which is insufficient to exceed the threshold voltage. Depending on the amount of charge stored in the charge trapping medium, either a current flows or does not flow, indicating whether or not the charge trapping medium stores charge or whether the charge trapping medium has been erased by the neutralization of charge on the charge trapping medium.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A charge trapping non-volatile memory comprising:
a gate electrode;
a blocking layer under said gate electrode;
a charge trapping medium including a first dielectric layer and a metal or semimetal layer; and
an injection tunnel layer under said charge trapping medium.

2. The memory of claim 1 wherein said metal or semimetal layer is less than 15 nanometers in thickness.

3. The memory of claim 1 wherein said charge trapping medium includes a second dielectric layer, said first and second dielectric layers sandwiching said metal or semimetal layer, said first and second dielectric layers each having a relative dielectric constant greater than 3.9.

4. The memory of claim 3 wherein said first and second dielectric layers have thicknesses of less than 10 nanometers.

5. The memory of claim 3 wherein said metal or semimetal layer has a lower energy than either of said dielectric layers.

6. The memory of claim 1 wherein said injection tunnel layer has a thickness of less than 15 nanometers.

7. The memory of claim 1 wherein the charge trapping medium has a thickness of about 30 nanometers or less.

8. A method comprising:
forming a charge trapping medium for a non-volatile memory having a pair of dielectric layers sandwiching a metal or semimetal layer.

9. The method of claim 8 including forming said charge trapping medium over an injection tunnel layer having a thickness less than 15 nanometers.

10. The method of claim 9 including forming said injection tunnel layer with a thickness of about 5 nanometers.

11. The method of claim 8 including forming a stack, including a gate electrode, a blocking layer, the charge trapping medium, and an injection tunnel layer, said stack having self-aligned edges.

12. The method of claim 8 including forming the charge trapping medium to have a thickness less than 30 nanometers.

13. The method of claim 8 including forming said charge trapping medium so that the metal or semimetal layer has a lower energy than the surrounding dielectric layers.

14. An apparatus comprising:
a substrate;
a charge trapping medium over said substrate;
a gate electrode over said charge trapping medium; and
said charge trapping medium including a metal or semimetal layer sandwiched by dielectric layers.

15. The apparatus of claim 14 including an injection tunnel Layer between said charge trapping medium and said substrate, said injection tunnel layer having a thickness of less than 15 nanometers.

16. The apparatus of claim 14 including a blocking layer between said gate electrode and said charge trapping medium.

17. The apparatus of claim 14 including a stack of a gate electrode, a blocking layer, the charge trapping medium, and an injection tunnel layer, said stack having self-aligned edges.

18. The apparatus of claim 14 wherein said metal or semimetal layer is less than 15 nanometers in thickness.

19. The apparatus of claim 14 wherein said charge trapping medium dielectric layers have a relative dielectric constant greater than 3.9.

20. The apparatus of claim 14 wherein said charge trapping medium has a thickness of about 30 nanometers or less.
